(19) United States
(12) Patent Application Publication
(10) Pub. No.: US 2019/0103360 A1
(43) Pub. Date: Apr. 4, 2019

(54) FLEXIBLE CHIP PACKAGE

(71) Applicants: Industrial Technology Research Institute, Hsinchu (TW); Intellectual Property Innovation Corporation, Hsinchu (TW)

(72) Inventors: Cheng-Hung Yu, Taoyuan City (TW); Tai-Jui Wang, Kaohsiung City (TW); Chieh-Wei Feng, Taoyuan City (TW); Shih-Kuang Chiu, Taichung City (TW); Ming-Huan Yang, Hsinchu City (TW)

(73) Assignees: Industrial Technology Research Institute, Hsinchu (TW); Intellectual Property Innovation Corporation, Hsinchu (TW)

(21) Appl. No.: 15/919,222

(22) Filed: Mar. 13, 2018

Related U.S. Application Data
(60) Provisional application No. 62/566,334, filed on Sep. 30, 2017.

(30) Foreign Application Priority Data
Dec. 25, 2017 (TW) 106145487

(51) Int. Cl. H01L 23/538; H01L 23/00; H01L 23/31

(52) U.S. Cl. CPC H01L 23/5387; H01L 24/09; H01L 2224/02373; H01L 24/32; H01L 23/3121

(57) ABSTRACT

A flexible chip package is provided. The flexible chip package includes a first flexible substrate; a first redistribution layer disposed on the first flexible substrate; a second flexible substrate; a second redistribution layer disposed on the second flexible substrate; a semiconductor chip disposed between the first and second redistribution layers and electrically connected to at least one of the first and second redistribution layers; and a first bonding layer disposed between the first and second redistribution layers and encapsulating the semiconductor chip, wherein the first bonding layer, the first redistribution layer and the second redistribution layer are between the first flexible substrate and the second flexible substrate.

### CROSS-REFERENCE TO RELATED APPLICATION

This application claims the priority benefits of U.S. provisional application Ser. No. 62/566,334, filed on Sep. 30, 2017 and Taiwan application serial no. 106145487, filed on Dec. 25, 2017. The entirety of each of the above-mentioned patent applications is hereby incorporated by reference herein and made a part of this specification.

### BACKGROUND

### 1. Field of the Disclosure

This disclosure is related to a chip package, and also related to a flexible chip package.

### 2. Description of Related Art

With the progress of science and technology, electronic products are moving toward the trend of lightweight and miniaturization. Taking the application of smart wearable electronic devices as an example, if the multi-chip package or the system in package used has the characteristics of flexibility and/or impact resistance, the reliability of the package structure may be ensured and the service life of the smart wearable electronic device may be improved. Accordingly, how to manufacture a package structure that takes the reliability, the flexibility characteristics and the impact resistance characteristics into account is actually the focus of research and development in the industry.

### SUMMARY

According to an embodiment of the present disclosure, a flexible chip package comprises a first flexible substrate; a first redistribution layer disposed on the first flexible substrate; a second flexible substrate; a second redistribution layer disposed on the second flexible substrate; a semiconductor chip disposed between the first and second redistribution layers and electrically connected to at least one of the first and second redistribution layers; and a first bonding layer disposed between the first and second redistribution layers and encapsulating the semiconductor chip, wherein the first bonding layer, the first redistribution layer and the second redistribution layer are between the first and the second flexible substrates.

According to another embodiment of the present disclosure, a flexible chip package comprises a first flexible substrate; a redistribution layer disposed on the first flexible substrate; a second flexible substrate; a stress adjustment layer disposed on the second flexible substrate; a semiconductor chip disposed between the redistribution layer and the stress adjustment layer and electrically connected to the redistribution layer; and a bonding layer disposed between the redistribution layer and the stress adjustment layer and encapsulating the semiconductor chip, wherein the bonding layer, the redistribution layer and the stress adjustment layer are between the first flexible substrate and the second flexible substrate.

According to some other embodiments of the present disclosure, a flexible chip package comprises a first flexible substrate; a first redistribution layer disposed on the first flexible substrate; a second flexible substrate; a second redistribution layer disposed on the second flexible substrate; a semiconductor chip embedded in at least one of the first and second flexible substrates and electrically connected to at least one of the first and second redistribution layers; and an anisotropic bonding layer disposed between the first and second redistribution layers, wherein the anisotropic bonding layer, the first redistribution layer and the second redistribution layer are between the first flexible substrate and the second flexible substrate.

According to some other embodiments of the present disclosure, a flexible chip package comprises a first flexible substrate; a first redistribution layer disposed on the first flexible substrate; a second flexible substrate; a second redistribution layer disposed on the second flexible substrate; a semiconductor chip disposed on at least one of the first and second redistribution layers and electrically connected to at least one of the first and second redistribution layers through a conductive material penetrating at least one of the first and the second flexible substrates; and an anisotropic bonding layer disposed between the first and second redistribution layers, wherein the anisotropic bonding layer, the first redistribution layer and the second redistribution layer are between the first flexible substrate and the second flexible substrate.

To make the present disclosure more comprehensible and understandable, the embodiments are described below in detail with the accompanying drawings.

### BRIEF DESCRIPTION OF THE DRAWINGS

FIG. 1 is a schematic diagram of a flexible chip package according to a first embodiment of the present disclosure.

FIGS. 2-10 are schematic views of other types of flexible chip packages according to the first embodiment of the present disclosure.

FIG. 11 is a schematic diagram of a flexible chip package according to a second embodiment of the present disclosure.

FIG. 12 is a schematic diagram of a flexible chip package according to a third embodiment of the present disclosure.

FIG. 13 is a schematic diagram of a flexible chip package according to a fourth embodiment of the present disclosure.

FIG. 14 is a schematic diagram of a flexible chip package according to a fifth embodiment of the present disclosure.

FIG. 15 is a schematic diagram of a flexible chip package according to a sixth embodiment of the present disclosure.

### DESCRIPTION OF THE EMBODIMENTS

The following disclosure of the specification provides different embodiments or examples to implement different features of various embodiments of the disclosure. However, the following disclosure of this specification is only some specific examples for describing each component and its arrangement, in order to simplify the description. Of course, these specific examples are not intended to limit the present disclosure. Additionally, different examples in the description of the present disclosure may use repeated reference characters and/or words. These repeated symbols or words are used for the sake of simplicity and clarity and are not intended to limit the relationship between the various embodiments and/or the appearance structure. Furthermore, if the following disclosure of the present specification describes forming a first feature on or above a second feature, that is, an embodiment comprising the formed first feature in direct contact with the second feature, also comprises an embodiment in which additional features may be formed between the first feature and the second feature without direct contact between the first feature and the second feature. The dimensions of the elements in the drawings are for ease of illustration and do not represent the actual scale of the elements.

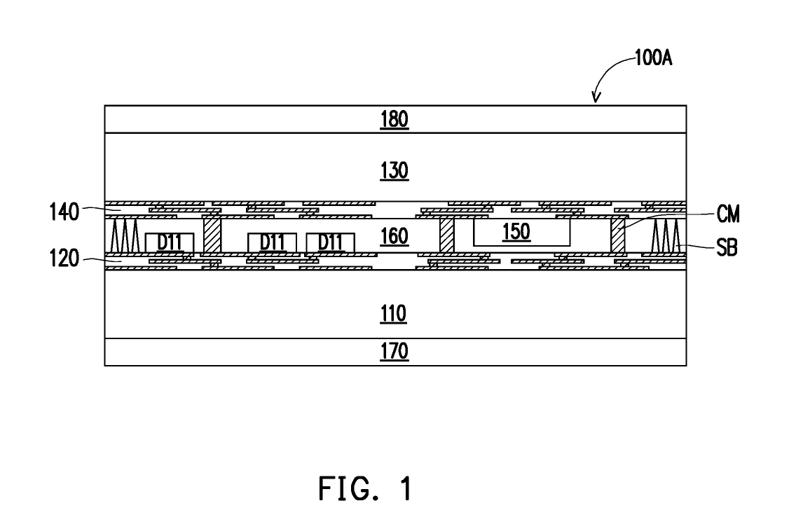

FIG. 1 is a schematic view of a flexible chip package according to a first embodiment of the present disclosure. Please refer to FIG. 1. A flexible chip package 100A of the present embodiment comprises a first flexible substrate 110, a first redistribution layer 120, a second flexible substrate 130, a second redistribution layer 140, a semiconductor chip 150, and a first bonding layer 160. The first redistribution layer 120 is disposed on the first flexible substrate 110, and the second redistribution layer 140 is disposed on the second flexible substrate 130. The semiconductor chip 150 is disposed between the first redistribution layer 120 and the second redistribution layer 140, and the semiconductor chip 150 is electrically connected to at least one of the first redistribution layer 120 and the second redistribution layer 140. The first bonding layer 160 is disposed between the first redistribution layer 120 and the second redistribution layer 140 and encapsulates the semiconductor chip 150. The first bonding layer 160, the first redistribution layer 120, and the second redistribution layer 140 are located between the first flexible substrate 110 and the second flexible substrate 130.

The first flexible substrate 110 may be a substrate, such as a polymer substrate, a thin glass substrate, a thin metal substrate, having certain flexural properties, and the Young's modulus of the substrate is, for example, between 0.001 GPa and 20 GPa. For example, the material of the first flexible substrate 110 may comprise polyimide (PI), polybenzoxazole (PBO), bis-benzocyclobuten (BCB), etc. Similarly, the second flexible substrate 130 may be a substrate, such as a polymer substrate, a thin glass substrate, a thin metal substrate, having certain flexural properties, and the Young's modulus of the substrate is, for example, between 0.001 GPa and 20 GPa. For example, the material of the second flexible substrate 130 may comprise polyimide (PI), polybenzoxazole (PBO), bis-benzocyclobuten (BCB), etc. In some embodiments, the first flexible substrate 110 and/or the second flexible substrate 130 may comprise a barrier layer (not shown) to block moisture, oxygen and the like from penetrating into the package, or the first flexible substrate 110 and/or the second flexible substrate 130 itself is a substrate having water and oxygen blocking function.

As shown in FIG. 1, the first redistribution layer 120 is disposed on the inner surface (i.e., the upper surface) of the first flexible substrate 110, and the second redistribution layer 140 is disposed on the inner surface (i.e., the lower surface) of the second flexible substrate 130. The inner surface (i.e., the upper surface) of the first flexible substrate 110 faces the inner surface (i.e., the lower surface) of the second flexible substrate 130. In some embodiments, the first redistribution layer 120 may be formed on the inner surface of the first flexible substrate 110 through a lithography/etching process or other suitable build-up processes. Similarly, the second redistribution layer 140 may be formed on the inner surface of the second flexible substrate 130 by a lithography/etching process or other suitable build-up processes. Here, the number of the circuit layers in the first redistribution layer 120 and the second redistribution layer 140 may be appropriately changed according to actual design requirements, and the disclosure is not limited to the illustration in the drawings.

In some embodiments, the semiconductor chip 150 disposed between the first redistribution layer 120 and the second redistribution layer 140 may be in contact with the second redistribution layer 140 and electrically connected to the second redistribution layer 140, and the semiconductor chip 150 and the first redistribution layer 120 may be separated from each other by the first bonding layer 160. In this case, the second redistribution layer 140 in contact with the semiconductor chip 150 may have a wiring with a smaller pitch arrangement to correspond to the pads on the semiconductor chip 150, and the first redistribution layer 120 spaced apart from the semiconductor chip 150 may have a wiring with a larger pitch arrangement. In other embodiments, not shown in the figure, the semiconductor chip 150 disposed between the first redistribution layer 120 and the second redistribution layer 140 may be in contact with the first redistribution layer 120 and be electrically connected to the first redistribution layer 120, and the semiconductor chip 150 and the second redistribution layer 140 may be separated from each other by the first bonding layer 160. In this case, the first redistribution layer 120 in contact with the semiconductor chip 150 may have wiring arranged in a smaller pitch to correspond to the pads on the semiconductor chip 150, and the second redistribution layer 140 spaced apart from the semiconductor chip 150 may have wiring arranged in a larger pitch.

As shown in FIG. 1, the first redistribution layer 120 and the second redistribution layer 140 are bonded to each other by the first bonding layer 160, and the first bonding layer 160 encapsulates the semiconductor chip 150, so that the semiconductor chip 150 may be fixed between the first redistribution layer 120 and the second redistribution layer 140. For example, the semiconductor chip 150 may be a CPU chip, a RF chip, a system on chip (SOC), or the like.

In some embodiments, the material of the first bonding layer 160 may be, for example, an acrylic resin, an epoxy resin, or other flexible bonding materials. The Young's modulus of the first bonding layer 160 is, for example, between 0.001 GPa and 20 GPa. In other embodiments, the material of the first bonding layer 160 may be, for example, an acrylic resin, an epoxy resin, or other flexible bonding materials. The Young's modulus of the first bonding layer 160 is, for example, between 0.01 GPa and 20 GPa. In other embodiments, the material of the first bonding layer 160 may be, for example, an acrylic resin, an epoxy resin, or other flexible bonding materials. The Young's modulus of the first bonding layer 160 is, for example, between 0.1 GPa and 20 GPa.

In some embodiments, in addition to the semiconductor chip 150, the first bonding layer 160 may further encapsulate at least one first device D11 disposed between the first redistribution layer 120 and the second redistribution layer 140 (three in the drawing). As shown in FIG. 1, the first device D11 is in contact with the first redistribution layer 120 and electrically connected to the first redistribution layer 120, and the first device D11 and the second redistribution layer 140 may be spaced apart from each other by the first bonding layer 160. In other embodiments, not shown in the drawings, the first device D11 may be in contact with the second redistribution layer 140 and be electrically connected to the second redistribution layer 140, and the first device D11 and the first redistribution layer 120 may be separated from each other by the first bonding layer 160. In some embodiments, the first device D11 comprises a sensor, a passive element (such as a resistor, a capacitor, an inductor, etc.), an electrostatic discharge protection element (such as a transistor, a diode, etc.), a battery, an antenna, a connector or a combination thereof. For example, the first device D11 may comprise a plurality of sensors of the same or different types, a plurality of passive elements of the same or different types, a combination of sensors and passive elements, or other combinations.

As shown in FIG. 1, the flexible chip package 100A of the present embodiment may further comprise a plurality of conductive materials CM encapsulated by the first bonding layer 160. The conductive materials CM respectively penetrate through the first bonding layer 160 to be electrically connected to the first redistribution layer 120 and the second redistribution layer 140. For example, the semiconductor chip 150 may be electrically connected to the first redistribution layer 120 through the second redistribution layer 140 and the conductive material CM. The first device D11 may be electrically connected to the second redistribution layer 140 through the first redistribution layer 120 and the conductive material CM. In some embodiments, the semiconductor chip 150 and the first device D11 may be electrically connected to each other through the second redistribution layer 140, the conductive material CM, and the first redistribution layer 120. For example, the aforementioned conductive materials CM may be solder balls, copper posts, an anisotropic conductive paste (ACP), or a combination of one or more other conductive materials.

As shown in FIG. 1, in order to further improve the reliability of the flexible chip package 100A, the flexible chip package 100A of the present embodiment may further comprise a sidewall barrier SB. The sidewall barrier SB is located between the first redistribution layer 120 and the second redistribution layer 140, and the sidewall barrier SB may be embedded in the first bonding layer 160 to surround the semiconductor chip 150. For example, the number of sidewall barriers SB may be one or more, and the sidewall barriers SB may have a continuous pattern surrounding the semiconductor chip 150 or a discontinuous pattern surrounding the semiconductor chip 150. However, in other embodiments, the cross section of the sidewall barrier SB perpendicular to the first flexible substrate 110 is, for example, a triangle, a trapezoid, a rectangle, a polygon, a circle, an ellipse or a pattern with other shapes. This disclosure is not limited thereto.

As shown in FIG. 1, the flexible chip package 100A of the present embodiment may further comprise a first cover layer 170 and/or a second cover layer 180. The first cover layer 170 is disposed on the first flexible substrate 110. The first cover layer 170 and the first redistribution layer 120 are respectively located on two opposite sides of the first flexible substrate 110. The second cover layer 180 is disposed on the second flexible substrate 130, and the second cover layer 180 and the second redistribution layer 140 are respectively disposed on two opposite sides of the second flexible substrate 130. In this embodiment, the first cover layer 170 and the second cover layer 180 are, for example, an impact-resistant and/or scratch-resistant material layer. The first cover layer 170 covers the outer surface (i.e., the lower surface) of the first flexible substrate 110, and the second cover layer 180 covers the outer surface (i.e., the upper surface) of the second flexible substrate 130. The first cover layer 170 and the second cover layer 180 may be a single-layer structure or a multi-layer composite structure comprising an impact-resistant structure and a scratch-resistant structure, for example. The impact-resistant structure of the first cover layer 170 may be disposed between the first flexible substrate 110 and the scratch-resistant structure, and the impact-resistant structure of the second cover layer 180 may be disposed between the second flexible substrate 130 and the scratch-resistant structure. In addition, the first cover layer 170 and the second cover layer 180 may be the same structure or different structures.

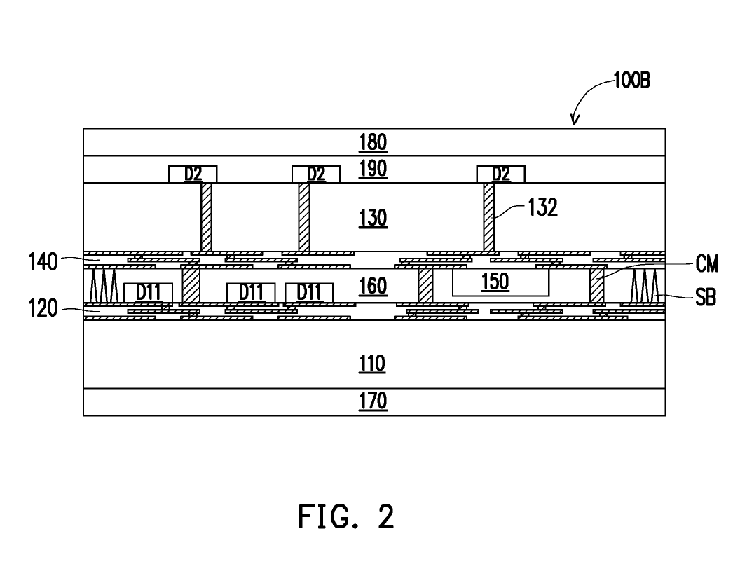

FIGS. 2-10 are schematic diagrams of other types of flexible chip packages according to the first embodiment of the present disclosure. Please refer to FIG. 2. The flexible chip package 100B is similar to the flexible chip package 100A, and only the structural differences will be described below in detail. The flexible chip package 100B may further comprise at least one second device D2 and a second bonding layer 190. The second device D2 is disposed between the second cover layer 180 and the second flexible substrate 130. The second bonding layer 190 is disposed between the second cover layer 180 and the second flexible substrate 130 to encapsulate the second device D2. The second device D2 and the second cover layer 180 may be spaced apart from each other by the second bonding layer 190. The second device D2 is in contact with the conductive material 132 and the second flexible substrate 130. The second device D2 may be electrically connected to the second redistribution layer 140 by the conductive material 132 penetrating the second flexible substrate 130.

The second device D2 comprises a sensor, a passive element (such as a resistor, a capacitor, an inductor, etc.), an electrostatic discharge protection element (such as a transistor, a diode, etc.), a battery, an antenna, a connector or a combination thereof. For example, the second device D2 may comprise a plurality of sensors of the same or different types, a plurality of passive elements of the same or different types, a combination of sensors and passive elements, or other combinations.

The material of the second bonding layer 190 may be, for example, an acrylic resin, an epoxy resin, or other flexible bonding materials. The Young's modulus of the second bonding layer 190 is, for example, between 0.001 GPa and 20 GPa. In other embodiments, the material of the second bonding layer 190 may be, for example, an acrylic resin, an epoxy resin, or other flexible bonding materials. The Young's modulus of the second bonding layer 190 is, for example, between 0.01 GPa and 20 GPa. In other embodiments, the material of the second bonding layer 190 may be, for example, an acrylic resin, an epoxy resin, or other flexible bonding materials. The Young's modulus of the second bonding layer 190 is, for example, between 0.1 GPa and 20 GPa.

As shown in FIG. 2, the semiconductor chip 150 disposed between the first redistribution layer 120 and the second redistribution layer 140 may be in contact with the first redistribution layer 120 and electrically connected to the first redistribution layer 120. The semiconductor chip 150 and the second redistribution layer 140 may be spaced apart from each other by the first bonding layer 160. In this case, the first redistribution layer 120 in contact with the semiconductor chip 150 may have wiring arranged in a smaller pitch to correspond to the pads on the semiconductor chip 150, and the second redistribution layer 140 spaced apart from the semiconductor chip 150 may have wiring arranged in a larger pitch. In addition, the semiconductor chip 150 and the second device D2 may be electrically connected to each other through the first redistribution layer 120, the conductive material CM, the second redistribution layer 140 and the conductive material 132. Similarly, the semiconductor chip 150 and the first device D11 may be electrically connected to each other through the first redistribution layer 120.

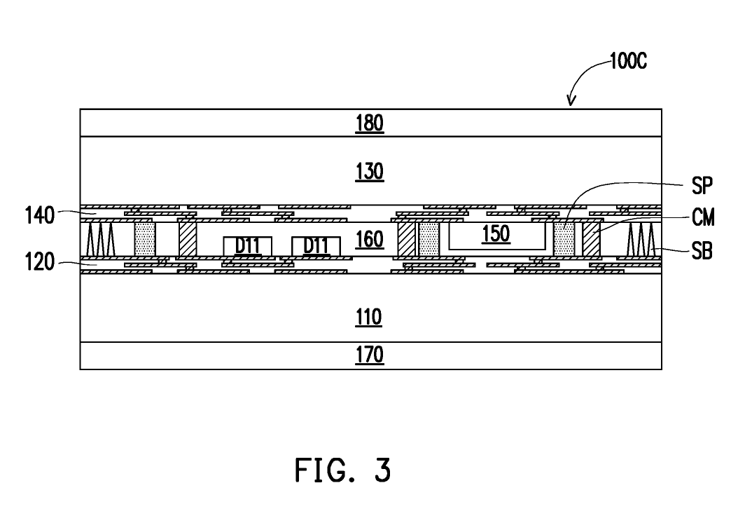

Please refer to FIG. 3. The flexible chip package 100C is similar to the flexible chip package 100A, and only the structural differences will be described below in detail. As shown in FIG. 3, the flexible chip package 100C may further comprise a plurality of support pillars SP. The support pillars SP penetrate through the first bonding layer 160. The support pillars SP are in contact with the first redistribution layer 120 and the second redistribution layer 140, so as to provide a structural support between the first redistribution layer 120 and the second redistribution layer 140. For example, the material of the support pillars SP comprises a dielectric material or other materials that have structural support capabilities. In the flexible chip package 100C, the distribution of the support pillars SP helps to maintain the thickness of the first bonding layer 160.

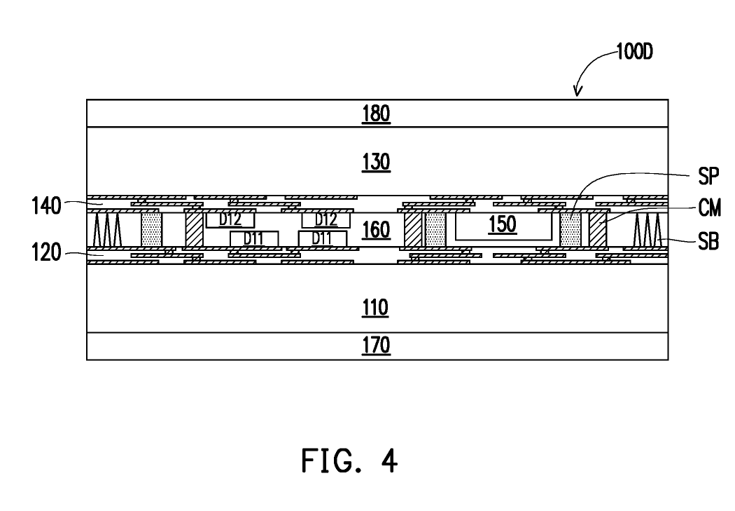

Please refer to FIG. 4. The flexible chip package 100D is similar to the flexible chip package 100C, and only the structural differences will be described below in detail. As shown in FIG. 4, the flexible chip package 100D may further comprises at least one first device D12 (two in the drawing) disposed between the first redistribution layer 120 and the second redistribution layer 140. The first device D12 is in contact with the second redistribution layer 140 and electrically connected to the second redistribution layer 140. The first device D12 and the first redistribution layer 120 may be separated from each other by the first bonding layer 160. For example, the first device D12 comprises a sensor, a passive element (such as a resistor, a capacitor, an inductor, etc.), an electrostatic discharge protection element (such as a transistor, a diode, etc.), a battery, an antenna, a connector or a combination thereof. For example, the first device D12 may comprise at least one sensor, at least one passive element, at least one battery, a combination of sensors and batteries, or other combinations.

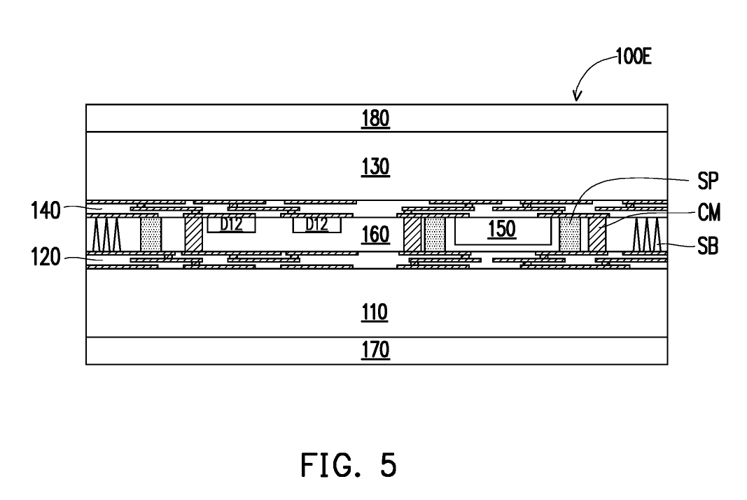

Please refer to FIG. 5. The flexible chip package 100E is similar to the flexible chip package 100D, and only the structural differences will be described below in detail. As shown in FIGS. 4 and 5, the flexible chip package 100E omits the arrangement of the first device D11 in the flexible chip package 100D.

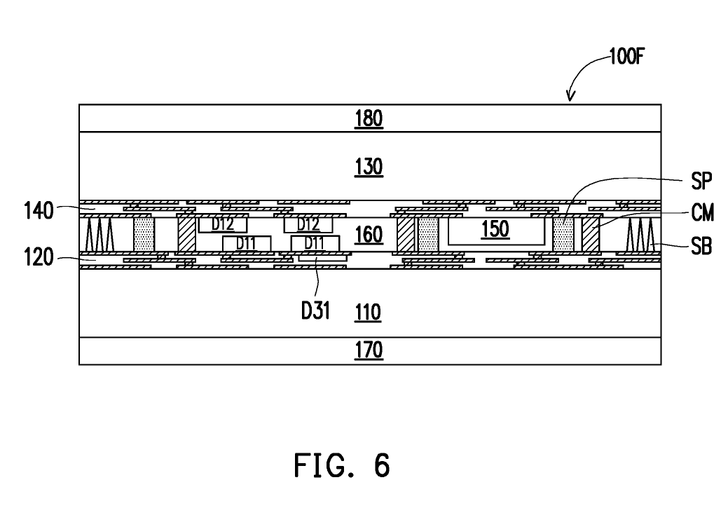

Please refer to FIG. 6. The flexible chip package 100F is similar to the flexible chip package 100D, and only the structural differences will be described below in detail. As shown in FIG. 6, the flexible chip package 100F further comprises at least one third device D31 (one in the drawing). The third device D31 is embedded in the first redistribution layer 120, and the third device D31 is electrically connected to the wiring in the first redistribution layer 120. That is, the third device D31 is integrated in the fabrication of the first redistribution layer 120. In addition, the semiconductor chip 150 and the third device D31 may be electrically connected to each other through the first redistribution layer 120, the conductive material CM, and the second redistribution layer 140. In other non-illustrated embodiments, the first device D11 or the first device D12 may also be omitted.

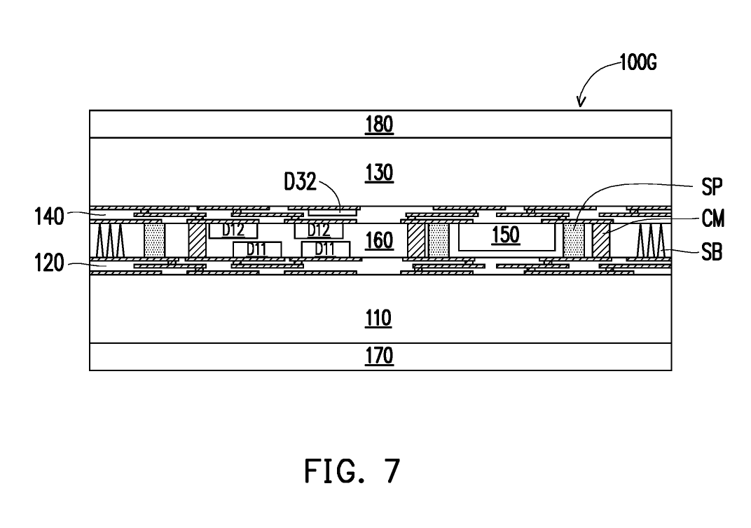

Please refer to FIG. 7. The flexible chip package 100G is similar to the flexible chip package 100D, and only the structural differences will be described below in detail. As shown in FIG. 7, the flexible chip package 100G may further comprise at least one third device D32 (one is shown in the figure). The third device D32 is embedded in the second redistribution layer 140, and the third device D32 is electrically connected to the wiring in the second redistribution layer 140. That is, the third device D32 is integrated in the fabrication of the second redistribution layer 140. In addition, the semiconductor chip 150 and the third device D32 may be electrically connected to each other through the second redistribution layer 140. In other non-illustrated embodiments, the first device D11 or the first device D12 may also be omitted.

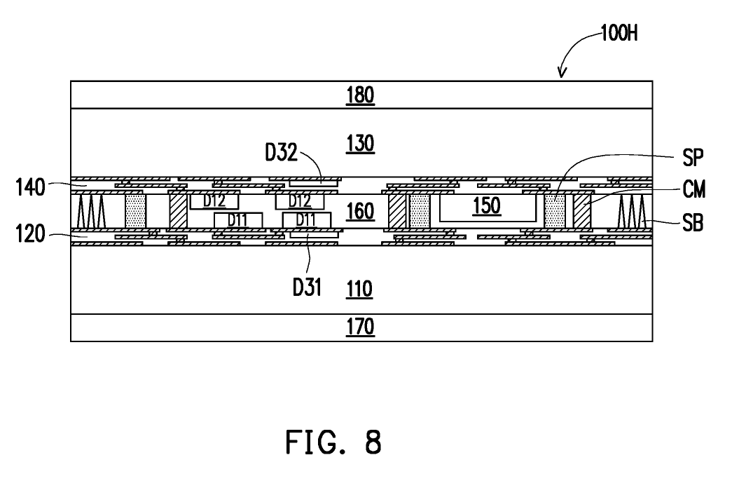

Please refer to FIG. 8. The flexible chip package 100H is similar to the flexible chip package 100D, and only the structural differences will be described below in detail. As shown in Fig, 8, the flexible chip package 100H may further comprise a third device D31 (one is shown in the figure) and at least one third device D32 (one is shown in the figure). The third device D31 is embedded in the first redistribution layer 120, and the third device D31 is electrically connected to the wiring in the first redistribution layer 120. The third device D32 is embedded in the second redistribution layer 140, and the third device D32 is electrically connected to the wiring in the second redistribution layer 140. That is, the third device D31 is integrated in the fabrication of the first redistribution layer 120, and the third device D32 is integrated in the fabrication of the second redistribution layer 140. In addition, the semiconductor chip 150 and the third device D31 may be electrically connected to each other through the first redistribution layer 120, the conductive material CM, and the second redistribution layer 140. The semiconductor chip 150 and the third device D32 may be electrically connected to each other through the second redistribution layer 140.

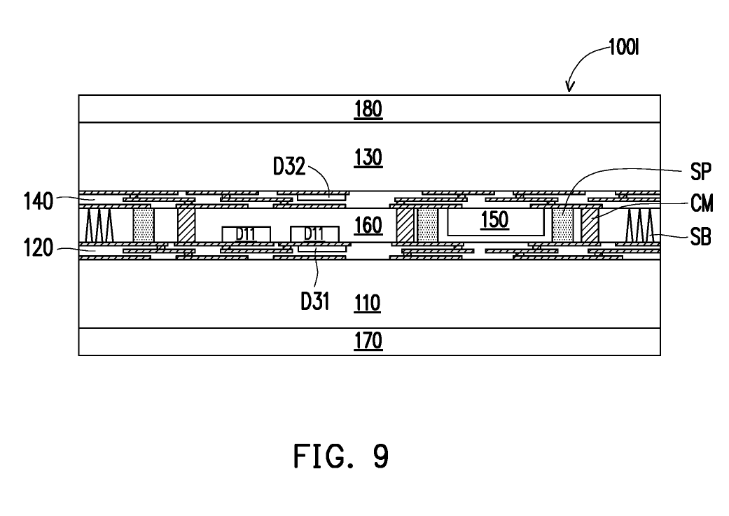

Please refer to FIG. 9. The flexible chip package 100I is similar to the flexible chip package 100H, and only the structural differences will be described below in detail. As shown in FIGS. 8 and 9, the flexible chip package 100I omits the arrangement of the first device D12 in the flexible chip package 100H.

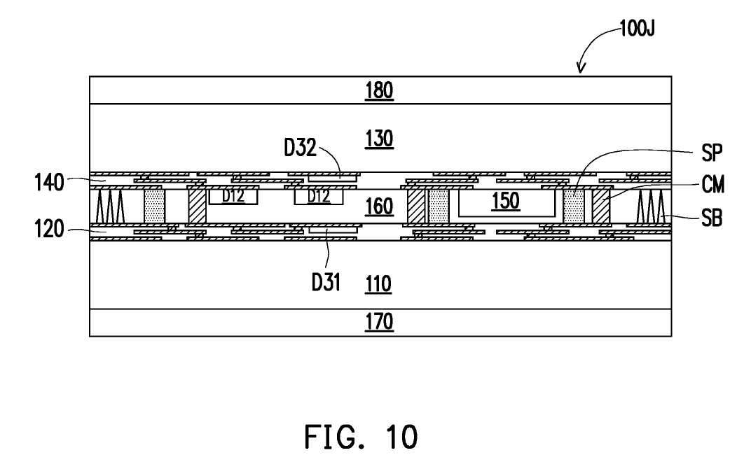

Please refer to FIG. 10. The flexible chip package 100J is similar to the flexible chip package 100H, and only the structural differences will be described below in detail. As shown in FIGS. 8 and 10, the flexible chip package 100J omits the arrangement of the first device D11 in the flexible chip package 100H. However, in other embodiments, the flexible chip packages 100D to 100J illustrated in FIGS. 4-10 may omit the arrangement of the support pillars SP. In other words, the conductive material CM in the flexible chip packages 100D to 100J also has a function of maintaining the thickness of the first bonding layer 160 in addition to the function of electrical connection.

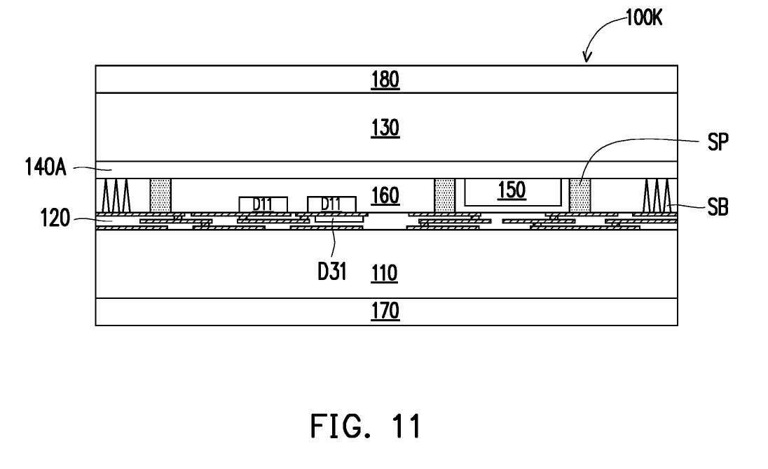

FIG. 11 is a schematic diagram of a flexible chip package according to a second embodiment of the present disclosure. Referring to FIG. 1 and FIG. 11, the flexible package 100K is similar to the flexible package 100A, so the detailed description will be given below only for the structural differences. As shown in FIGS. 1 and 11, the flexible chip package 100K omits the arrangement of the second redistribution layer 140 and the conductive material CM in the flexible chip package 100A, and a stress adjustment layer 140A is provided between the second flexible substrate 130 and the first bonding layer 160. The flexible chip package 100K further comprises a plurality of support pillars SP. The support pillars SP penetrate the first bonding layer 160, and the support pillars SP contact the first redistribution layer 120 and the stress adjustment layer 140A to provide structural support between the first redistribution layer 120 and the stress adjustment layer 140A. The semiconductor chip 150 disposed between the first redistribution layer 120 and the stress adjustment layer 140A may be in contact with the first redistribution layer 120 and be electrically connected to the first redistribution layer 120. The semiconductor chip 150 and the stress adjusting layer 140A may be spaced apart from each other by the first bonding layer 160. In this case, portions of the first redistribution layer 120 in contact with the semiconductor chip 150 may have wirings arranged in a smaller pitch to correspond to the pads on the semiconductor chip 150. The portion of the first redistribution layer 120 in contact with the first device D11 may have wiring arranged in a larger pitch.

In some embodiments, the semiconductor chip 150 and the first device D11 as well as the semiconductor chip 150 and the third device D31 may be electrically connected to each other through the first redistribution layer 120. In addition, the support pillars SP may be in contact with the first redistribution layer 120 and the stress adjustment layer 140A to provide structural support between the first redistribution layer 120 and the stress adjustment layer 140A. For example, the material of the stress adjusting layer 140A may comprise a metal, a polyimide, a resin material, silicon oxide (SiOx), silicon nitride (SiNx), silicon oxynitride (SiNxOy), or a combination thereof. In some embodiments, the aforementioned stress adjustment layer 140A may be a single-layer structure or a multi-layer structure. Through the material selection and thickness design of the stress adjusting layer 140A, the stress adjusting layer 140A may provide proper counter-stress in the flexible chip package 100K, so as to effectively reduce the stress imbalance in the flexible package 100K and further improve the flexing resistance of the flexible package 100K.

As shown in FIG. 11, the flexible chip package 100K of the present embodiment further comprises a first cover layer 170 and/or a second cover layer 180. The first cover layer 170 is disposed on the first flexible substrate 110, and the first cover layer 170 and the first redistribution layer 120 are respectively located on two opposite sides of the first flexible substrate 110. The second cover layer 180 is disposed on the second flexible substrate 130, and the second cover layer 180 and the stress adjusting layer 140A are respectively disposed on two opposite sides of the second flexible substrate 130. In this embodiment, the first cover layer 170 and the second cover layer 180 are, for example, an impact-resistant material layer having a flexible property. The first cover layer 170 covers the outer surface (i.e., the lower surface) of the first flexible substrate 110, and the second cover layer 180 covers the outer surface (i.e., the upper surface) of the second flexible substrate 130. The first cover layer 170 and the second cover layer 180 may be a single-layer structure or a multi-layer composite structure, for example, comprising an impact-resistant structure and a scratch-resistant structure. The impact-resistant structure of the first cover layer 170 is disposed between the first flexible substrate 110 and the scratch-resistant structure, and the impact-resistant structure of the second cover layer 180 is disposed between the second flexible substrate 130 and the scratch-resistant structure. The first cover layer 170 and the second cover layer 180 may be the same structure or different structures.

In the embodiment shown in FIG. 11, the first cover layer 170 may further comprise a barrier layer (not shown), and the second cover layer 180 may further comprise a barrier layer (not shown) to block moisture, oxygen, and etc. from penetrating into the package. A bonding layer (not shown) may be selectively disposed between the first flexible substrate 110 and the first cover layer 170 and/or between the second flexible substrate 130 and the second cover layer 180, so that the first flexible substrate 110 and the first cover layer 170 are bonded to each other, and/or the second flexible substrate 130 and the second cover layer 180 are bonded to each other. The material of the bonding layer is, for example, an acrylic resin, an epoxy resin, or other flexible bonding materials.

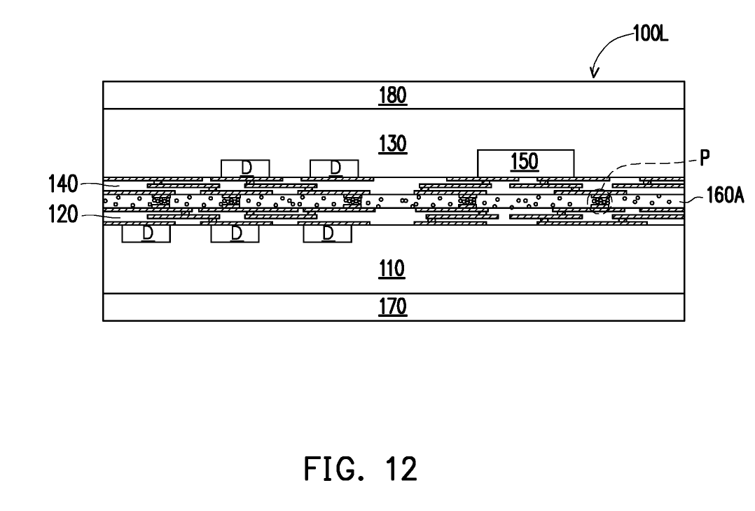

FIG. 12 is a schematic view of a flexible chip package according to a third embodiment of the present disclosure. Referring to FIG. 12, the flexible chip package 100L of the present embodiment comprises a first flexible substrate 110, a first redistribution layer 120, a second flexible substrate 130, a second redistribution layer 140, a semiconductor chip 150 and an anisotropic bonding layer 160A. The first redistribution layer 120 is disposed on the inner surface (i.e., the upper surface) of the first flexible substrate 110, and the second redistribution layer 140 is disposed on the inner surface (i.e., the lower surface) of the second flexible substrate 130. The semiconductor chip 150 is embedded in at least one of the first flexible substrate 110 and the second flexible substrate 130, and the semiconductor chip 150 is electrically connected to at least one of the first redistribution layer 120 and the second redistribution layer 140. The anisotropic bonding layer 160A is disposed between the first redistribution layer 120 and the second redistribution layer 140. The anisotropic bonding layer 160A, the first redistribution layer 120, and the second redistribution layer 140 are located between the first flexible substrate 110 and the second flexible substrate 130.

As described above, the first flexible substrate 110, the first redistribution layer 120, the second flexible substrate 130, the second redistribution layer 140, and the semiconductor chip 150 in the flexible chip package 100L are similar to the flexible chip package 100A (shown in FIG. 1), and thus are not repeated here. Only the differences will be described below.

In the flexible chip package 100L, the semiconductor chip 150 may be embedded in a groove of the second flexible substrate 130 and be electrically connected to the second redistribution layer 140 on the lower surface of the second flexible substrate 130. In other words, the second redistribution layer 140 covers the lower surface of the second flexible substrate 130 and the active surface of the semiconductor chip 150, and is electrically connected to the semiconductor chip 150. As shown in FIG. 12, the semiconductor chip 150 is covered with the second flexible substrate 130. In this case, the second redistribution layer 140 in contact with the semiconductor chip 150 may have wirings arranged in a smaller pitch to correspond to the pads on the semiconductor chip 150, and the first redistribution layer 120 spaced apart from the semiconductor chip 150 may have wiring arranged in a larger pitch.

In other embodiments, not shown in the drawings, the semiconductor chip 150 may also be embedded in a groove of the first flexible substrate 110, and be electrically connected to the first redistribution layer 120 on the upper surface of the first flexible substrate 110. In other words, the first redistribution layer 120 covers the upper surface of the first flexible substrate 110 and the active surface of the semiconductor chip 150, and is electrically connected to the semiconductor chip 150. That is, the semiconductor chip 150 is covered by the first flexible substrate 110. In this case, the first redistribution layer 120 in contact with the semiconductor chip 150 may have wiring arranged in a smaller pitch to correspond to the pads on the semiconductor chip 150, and the second redistribution layer 140 spaced apart from the semiconductor chip 150 may have wiring arranged in a larger pitch.

In some embodiments, the first redistribution layer 120 and the second redistribution layer 140 respectively have corresponding protruding portions P. The protruding portions P of the first redistribution layer 120 and the second redistribution layer 140 may be bonded to each other by the anisotropic bonding layer 160A, so that the first redistribution layer 120 and the second redistribution layer 140 may be electrically connected to each other by the anisotropic bonding layer 160A in a partial area. For example, the anisotropic bonding layer 160A may be an anisotropic conductive layer, such as an anisotropic conductive film (ACF) or an anisotropic conductive paste (ACP).

In some embodiments, the flexible chip package 100L may further comprise at least one device D (five devices are shown in FIG. 12). These devices D may be embedded in at least one of the first flexible substrate 110 and the second flexible substrate 130. As shown in FIG. 12, the devices D may be embedded in the first flexible substrate 110 and the second flexible substrate 130. The devices D comprise a sensor, a passive element (such as a resistor, a capacitor, an inductor, etc.), an electrostatic discharge protection element (such as a transistor, a diode, etc.), a battery, an antenna, a connector or a combination thereof. For example, the devices D1 may comprise a plurality of sensors of the same or different types, a plurality of passive elements of the same or different types, a combination of sensors and passive elements, or other combinations.

As shown in FIG. 12, the flexible chip package 100L of the present embodiment may further comprise a first cover layer 170 and/or a second cover layer 180. The first cover layer 170 is disposed on the first flexible substrate 110. The first cover layer 170 and the first redistribution layer 120 are respectively located on two opposite sides of the first flexible substrate 110. The second cover layer 180 is disposed on the second flexible substrate 130. The second cover layer 180 and the second redistribution layer 140 are respectively disposed on two opposite sides of the second flexible substrate 130. In this embodiment, the first cover layer 170 and the second cover layer 180 are, for example, an impact-resistant and/or scratch-resistant material layer. The first cover layer 170 covers the outer surface (i.e., the lower surface) of the first flexible substrate 110, and the second cover layer 180 covers the outer surface (i.e., the upper surface) of the second flexible substrate 130. The first cover layer 170 and the second cover layer 180 may be a single-layer or a multi-layer composite structures comprising an impact-resistant structure and a scratch-resistant structure, for example. The impact-resistant structure of the first cover layer 170 may be disposed between the first flexible substrate 110 and the scratch-resistant structure, and the impact-resistant structure of the second cover layer 180 may be disposed between the second flexible substrate 130 and the scratch-resistant structure. In addition, the first cover layer 170 and the second cover layer 180 may be the same structure or different structures.

In the embodiment shown in FIG. 12, the first cover layer 170 may further comprise a barrier layer (not shown) and the second cover layer 180 may further comprise a barrier layer (not shown) to block moisture, oxygen, and etc. from penetrating into the package. A bonding layer (not shown) may be selectively disposed between the first flexible substrate 110 and the first cover layer 170 and/or between the second flexible substrate 130 and the second cover layer 180, so that the first flexible substrate 110 and the first cover layer 170 are bonded to each other, and/or the second flexible substrate 130 and the second cover layer 180 are bonded to each other. The material of the bonding layer is, for example, an acrylic resin, an epoxy resin, or other flexible bonding materials.

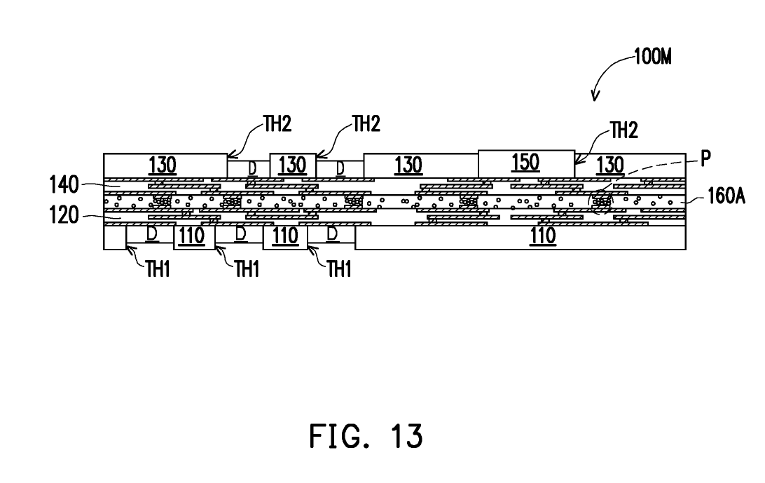

FIG. 13 is a schematic view of a flexible chip package according to a fourth embodiment of the present disclosure. Please refer to FIGS. 12 and 13. The flexible chip package 100M of the present embodiment is similar to the flexible chip package 100L, and only the structural differences will be described below in detail. As shown in FIGS. 12 and 13, the flexible chip package 100M omits the arrangement of the first cover layer 170 and the second cover layer 180 in the flexible chip package 100L. In addition, in the flexible chip package 100M, the first flexible substrate 110 has through holes TH1, and the second flexible substrate 130 has through holes TH2. The semiconductor chip 150 and the devices D are embedded in the through holes TH1 of the first flexible substrate 110 and the through holes TH2 of the second flexible substrate 130, and the semiconductor chip 150 is exposed by the through holes TH1 and TH2. In some alternative embodiment, the through holes may only be formed in the first flexible substrate 110 or the second flexible substrate 130.

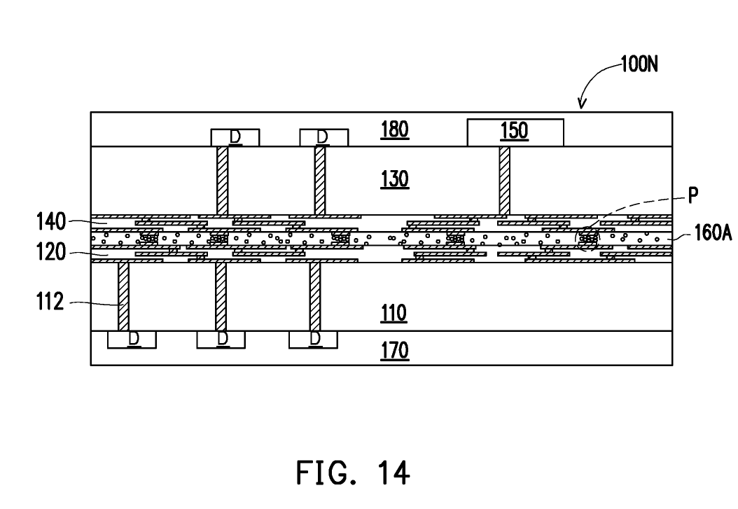

FIG. 14 is a schematic view of a flexible chip package according to a fifth embodiment of the present disclosure. Referring to FIGS. 13 and 14, the flexible chip package 100N of the present embodiment is similar to the flexible chip package 100M, and only the structural differences will be described in detail below. As shown in FIGS. 13 and 14, in the flexible chip package 100N, the semiconductor chip 150 is disposed on at least one of the first flexible substrate 110 and the second flexible substrate 130. A part of the devices D disposed on the first flexible substrate 110 may be electrically connected to the first redistribution layer 120 through the conductive materials 112 penetrating the first flexible substrate 110. The semiconductor chip 150 and the a part of the devices D disposed on the second flexible substrate 130 are electrically connected to the second redistribution layer 140 through the conductive materials 132 passing through the second flexible substrate 130.

As shown in FIG. 14, the flexible chip package 100N of the present embodiment may further comprise a first cover layer 170 and/or a second cover layer 180. The first cover layer 170 is disposed on the lower surface of the first flexible substrate 110, so as to cover a part of the devices D disposed on the first flexible substrate 110. The first cover layer 170 and the first redistribution layer 120 are respectively located on two opposite sides of the first flexible substrate 110. The second cover layer 180 is disposed on the upper surface of the second flexible substrate 130 so as to cover the semiconductor chip 150 and a part of the devices D disposed on the second flexible substrate 130. The second cover layer 180 and the second redistribution layer 140 are respectively disposed on two opposite sides of the second flexible substrate 130. In this embodiment, the first cover layer 170 and the second cover layer 180 are, for example, an impact-resistant and/or scratch-resistant material layer. The first cover layer 170 covers the outer surface (i.e., the lower surface) of the first flexible substrate 110, and the second cover layer 180 covers the outer surface (i.e., the upper surface) of the second flexible substrate 130.

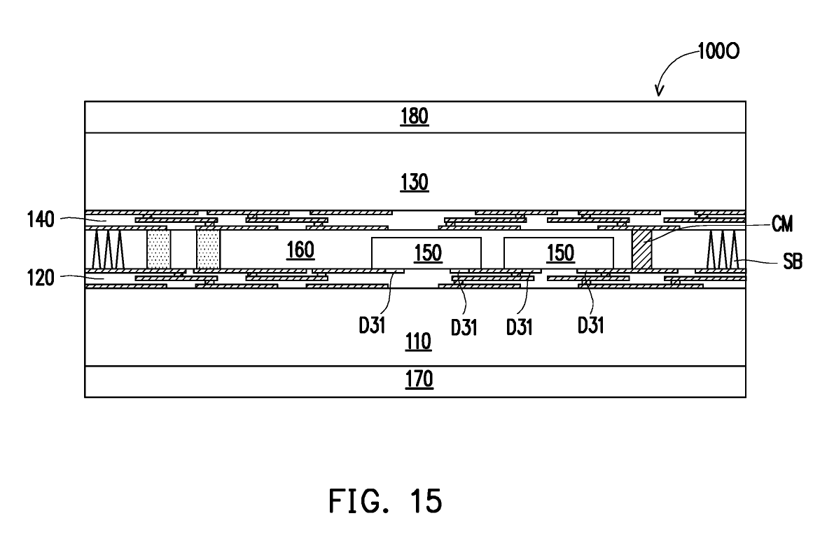

FIG. 15 is a schematic diagram of a flexible chip package according to a sixth embodiment of the present disclosure. Referring to FIG. 15, the flexible chip package 1000 of the present embodiment comprises a first flexible substrate 110, a first redistribution layer 120, a second flexible substrate 130, a second redistribution layer 140, a semiconductor chip 150, a first bonding layer 160 and third devices D31. The first redistribution layer 120 is disposed on the first flexible substrate 110, and the second redistribution layer 140 is disposed on the second flexible substrate 130. The semiconductor chip 150 is disposed between the first redistribution layer 120 and the second redistribution layer 140, and the semiconductor chip 150 is electrically connected to at least one of the first redistribution layer 120 and the second redistribution layer 140. Although the semiconductor chip 150 shown in FIG. 15 is electrically connected to the first redistribution layer 120, but the embodiment is not limited thereto. The first bonding layer 160 is disposed between the first redistribution layer 120 and the second redistribution layer 140 and encapsulates the semiconductor chip 150. The first bonding layer 160, the first redistribution layer 120, and the second redistribution layer 140 are located between the first flexible substrate 110 and the second flexible substrate 130. In some embodiments, the third devices D31 are embedded in the first redistribution layer 120, and the third devices D31 are electrically connected to the semiconductor chip 150 through wiring in the first redistribution layer 120. In other embodiments, the semiconductor chip 150 may be disposed on the second redistribution layer 140 and electrically connected to the second redistribution layer 140. In this case, the third devices D31 may be embedded in the second redistribution layer 140, and the third devices D31 may be electrically connected to the semiconductor chip 150 through wiring in the second redistribution layer 140. In addition, the third devices D31 are, for example, an electrostatic discharge protection element (for example, a transistor, a diode, etc.). The third devices D31 are disposed adjacent to the contacts of the semiconductor chip 150, for example, to prevent the electrostatic discharge from damaging the semiconductor chip 150.

The first flexible substrate 110 may be a substrate, such as a polymer substrate, a thin glass substrate, a thin metal substrate, having certain flexural properties, and the Young's modulus of the substrate is, for example, between 0.001 GPa and 20 GPa. For example, the material of the first flexible substrate 110 may comprise polyimide (PI), polybenzoxazole (PBO), bis-benzocyclobuten (BCB), etc. Similarly, the second flexible substrate 130 may be a substrate, such as a polymer substrate, a thin glass substrate, a thin metal substrate, having certain flexural properties, and the Young's modulus of the substrate is, for example, between 0.001 GPa and 20 GPa. For example, the material of the second flexible substrate 130 may comprise polyimide (PI), polybenzoxazole (PBO), bis-benzocyclobuten (BCB), etc. In some embodiments, the first flexible substrate 110 and/or the second flexible substrate 130 may comprise a barrier layer (not shown) to block moisture, oxygen and the like from penetrating into the package, or the first flexible substrate 110 and/or the second flexible substrate 130 itself is a substrate having water and oxygen blocking function.

As shown in FIG. 15, the first redistribution layer 120 is disposed on the inner surface (i.e., the upper surface) of the first flexible substrate 110 and the second redistribution layer 140 is disposed on the inner surface (i.e., the upper surface) of the second flexible substrate 130. The inner surface (i.e., the upper surface) of the first flexible substrate 110 faces the inner surface (i.e., the lower surface) of the second flexible substrate 130. In some embodiments, the first redistribution layer 120 may be formed on the inner surface of the first flexible substrate 110 through a lithography/etching process or other suitable build-up processes. Similarly, the second redistribution layer 140 may be formed on the inner surface of the second flexible substrate 130 by a lithography/etching process or other suitable build-up processes. Here, the number of the circuit layers in the first redistribution layer 120 and the second redistribution layer 140 may be appropriately changed according to actual design requirements, and the disclosure is not limited to the illustration in the drawings.

In some embodiments, the semiconductor chip 150 disposed between the first redistribution layer 120 and the second redistribution layer 140 may be in contact with the first redistribution layer 120 and electrically connected to the first redistribution layer 120, and the semiconductor chip 150 and the second redistribution layer 140 may be separated from each other by the first bonding layer 160. In this case, the first redistribution layer 120 in contact with the semiconductor chip 150 may have a wiring with a smaller pitch arrangement to correspond to the pads on the semiconductor chip 150, and the second redistribution layer 140 spaced apart from the semiconductor chip 150 may have a wiring with a larger pitch arrangement.

As shown in FIG. 15, the first redistribution layer 120 and the second redistribution layer 140 are bonded to each other by the first bonding layer 160, and the first bonding layer 160 encapsulates the semiconductor chip 150 so that the semiconductor chip 150 may be fixed between the first redistribution layer 120 and the second redistribution layer 140. For example, the semiconductor chip 150 may be a CPU chip, a RF chip, a system on chip (SOC), or the like. In some embodiments, the material of the first bonding layer 160 may be, for example, an acrylic resin, an epoxy resin, or other flexible bonding materials. The Young's modulus of the first bonding layer 160 is, for example, between 0.001 GPa and 20 GPa. In other embodiments, the material of the first bonding layer 160 may be, for example, an acrylic resin, an epoxy resin, or other flexible bonding materials. The Young's modulus of the first bonding layer 160 is, for example, between 0.01 GPa and 20 GPa. In other embodiments, the material of the first bonding layer 160 may be, for example, an acrylic resin, an epoxy resin, or other flexible bonding materials. The Young's modulus of the first bonding layer 160 is, for example, between 0.1 GPa and 20 GPa.

As shown in FIG. 15, the flexible chip package 1000 of the present embodiment may further comprise a plurality of conductive materials CM encapsulated by the first bonding layer 160. The conductive materials CM respectively penetrate through the first bonding layer 160 to be electrically connected to the first redistribution layer 120 and the second redistribution layer 140. For example, the semiconductor chip 150 may be electrically connected to the second redistribution layer 140 through the first redistribution layer 120 and the conductive material CM. For example, the aforementioned conductive material CM may be a solder ball, a copper post, an anisotropic conductive paste (ACP), or a combination of one or more other conductive materials.

As shown in FIG. 15, in order to further improve the reliability of the flexible chip package 1000, the flexible chip package 1000 of the present embodiment may further comprise a sidewall barrier SB. The sidewall barrier SB is located between the first redistribution layer 120 and the second redistribution layer 140, and the sidewall barrier SB may be embedded in the first bonding layer 160 to surround the semiconductor chip 150. For example, the number of sidewall barriers SB may be one or more, and the sidewall barriers SB may have a continuous pattern surrounding the semiconductor chip 150 or a discontinuous pattern surrounding the semiconductor chip 150. However, in other embodiments, the cross section of the sidewall barrier SB perpendicular to the first flexible substrate 110 is, for example, a triangle, a trapezoid, a rectangle, a polygon, a circle, an ellipse or a pattern with other shapes. This disclosure is not limited thereto.

As shown in FIG. 15, the flexible chip package 1000 of the present embodiment may further comprise a first cover layer 170 and/or a second cover layer 180. The first cover layer 170 is disposed on the first flexible substrate 110. The first cover layer 170 and the first redistribution layer 120 are respectively located on two opposite sides of the first flexible substrate 110. The second cover layer 180 is disposed on the second flexible substrate 130. The second cover layer 180 and the second redistribution layer 140 are respectively disposed on two opposite sides of the second flexible substrate 130. In this embodiment, the first cover layer 170 and the second cover layer 180 are, for example, an impact-resistant and/or scratch-resistant material layer. The first cover layer 170 covers the outer surface (i.e., the lower surface) of the first flexible substrate 110, and the second cover layer 180 covers the outer surface (i.e., the upper surface) of the second flexible substrate 130. The first cover layer 170 and the second cover layer 180 may be a single-layer structure or a multi-layer composite structure comprising an impact-resistant structure and a scratch-resistant structure, for example. The impact-resistant structure of the first cover layer 170 may be disposed between the first flexible substrate 110 and the scratch-resistant structure, and the impact-resistant structure of the second cover layer 180 may be disposed between the second flexible substrate 130 and the scratch-resistant structure. In addition, the first cover layer 170 and the second cover layer 180 may be the same structure or different structures.

In summary, the above embodiments of the present disclosure provide a plurality of flexible chip packages, which may have flexural properties and/or impact resistance characteristics, which are beneficial to the improvement of reliability.

While the disclosure has been described by the above embodiments, it will be apparent to one of the ordinary skill in the art that modifications may also be made without departing from the spirit of the disclosure. Therefore, the protection scope of the present disclosure shall prevail as determined by the scope of the appended claims.

What is claimed is:

1. A flexible chip package, comprising:
a first flexible substrate;
a first redistribution layer disposed on the first flexible substrate;
a second flexible substrate;
a second redistribution layer disposed on the second flexible substrate;
a semiconductor chip disposed between the first and second redistribution layers and electrically connected to at least one of the first and second redistribution layers; and
a first bonding layer disposed between the first and second redistribution layers and encapsulating the semiconductor chip, wherein the first bonding layer, the first redistribution layer and the second redistribution layer are between the first flexible substrate and the second flexible substrate.

2. The flexible chip package of claim 1, further comprising a plurality of conductive materials penetrating through the first bonding layer to electrically connect the first and second redistribution layers.

3. The flexible chip package of claim 1, further comprising a plurality of support pillars penetrating through the first bonding layer to contact the first and second redistribution layers.

4. The flexible chip package of claim 1, further comprising a sidewall barrier embedded in the first bonding layer to surround the semiconductor chip.

5. The flexible chip package of claim 1, further comprising at least one first device disposed between the first and second redistribution layers and electrically connecting one of the first and second redistribution layers.

6. The flexible chip package of claim 5, wherein the at least one first device comprises a sensor, a passive element, an electrostatic discharge protection element, a battery, an antenna, a connector, or a combination thereof.

7. The flexible chip package of claim 1, further comprising:
a first cover layer disposed on the first flexible substrate, wherein the first cover layer and the first redistribution layer are respectively located on two opposite sides of the first flexible substrate; and
a second cover layer disposed on the second flexible substrate, wherein the second cover layer and the second redistribution layer are respectively located on two opposite sides of the second flexible substrate.

8. The flexible chip package of claim 7, further comprising:
at least one second device disposed between the second cover layer and the second flexible substrate, and the at least one second device electrically connecting to the second redistribution layer; and
a second bonding layer disposed between the second cover layer and the second flexible substrate and encapsulating the at least one second device.

9. The flexible chip package of claim 8, wherein the at least one second device comprises a sensor, a passive element, an electrostatic discharge protection element, a battery, an antenna, a connector, or a combination thereof.

10. The flexible chip package of claim 1, further comprising at least one third device, wherein the at least one third device is embedded in at least one of the first redistribution layer and the second redistribution layer, and the at least one third device comprises a sensor, a passive element, an electrostatic discharge protection element, a battery, an antenna, a connector, or a combination thereof.

11. A flexible chip package, comprising:
a first flexible substrate;
a redistribution layer disposed on the first flexible substrate;
a second flexible substrate;
a stress adjustment layer disposed on the second flexible substrate;
a semiconductor chip disposed between the redistribution layer and the stress adjustment layer and electrically connected to the redistribution layer; and
a bonding layer disposed between the redistribution layer and the stress adjustment layer and encapsulating the semiconductor chip, wherein the bonding layer, the redistribution layer and the stress adjustment layer are between the first flexible substrate and the second flexible substrate.

12. The flexible chip package of claim 11, further comprising a plurality of support pillars penetrating through the bonding layer to contact the redistribution layer and the stress adjustment layer.

13. The flexible chip package of claim 11, further comprising a sidewall barrier embedded in the bonding layer to surround the semiconductor chip.

14. The flexible chip package of claim 11, further comprising at least one device disposed between the redistribution layer and the stress adjustment layer, wherein the at least one device electrically connects to the redistribution layer, and the at least one device comprises a sensor, a passive element, an electrostatic discharge protection element, a battery, an antenna, a connector, or a combination thereof.

15. The flexible chip package of claim 11, further comprising:
a first cover layer disposed on the first flexible substrate, wherein the first cover layer and the redistribution layer are respectively located on two opposite sides of the first flexible substrate; and
a second cover layer disposed on the second flexible substrate, wherein the second cover layer and the stress adjustment layer are respectively located on two opposite sides of the second flexible substrate.

16. A flexible chip package, comprising:
a first flexible substrate;
a first redistribution layer disposed on the first flexible substrate;
a second flexible substrate;
a second redistribution layer disposed on the second flexible substrate;
a semiconductor chip embedded in at least one of the first and second flexible substrates and electrically connected to at least one of the first and second redistribution layers; and
an anisotropic bonding layer disposed between the first and second redistribution layers, wherein the anisotropic bonding layer, the first redistribution layer and the second redistribution layer are between the first flexible substrate and the second flexible substrate.

17. The flexible chip package of claim 16, wherein the semiconductor chip is embedded in a groove of at least one of the first and second flexible substrates and the semiconductor chip is covered by at least one of the first and second flexible substrates.

18. The flexible chip package of claim 16, wherein the semiconductor chip is embedded in a trough hole of at least one of the first and second flexible substrates and the semiconductor chip is exposed by the through hole.

19. The flexible chip package of claim 16, wherein the anisotropic bonding layer comprises an anisotropic conductive layer.

20. The flexible chip package of claim 16, further comprising at least one device embedded in at least one of the first and second flexible substrates, and the at least one device comprises a sensor, a passive element, an electrostatic discharge protection element, a battery, an antenna, a connector, or a combination thereof.

21. The flexible chip package of claim 16, further comprising:
a first cover layer disposed on the first flexible substrate, wherein the first cover layer and the first redistribution layer are respectively located on two opposite sides of the first flexible substrate; and
a second cover layer disposed on the second flexible substrate, wherein the second cover layer and the second redistribution layer are respectively located on two opposite sides of the second flexible substrate.

22. A flexible chip package, comprising:
a first flexible substrate;
a first redistribution layer disposed on the first flexible substrate;
a second flexible substrate;
a second redistribution layer disposed on the second flexible substrate;
a semiconductor chip disposed at least one of the first and second redistribution layers and electrically connected to at least one of the first and second redistribution layers through a conductive material penetrating at least one of the first and the second flexible substrates; and
an anisotropic bonding layer disposed between the first and second redistribution layers, wherein the anisotropic bonding layer, the first redistribution layer and the second redistribution layer are between the first flexible substrate and the second flexible substrate.

23. The flexible chip package of claim 22, wherein the anisotropic bonding layer comprises an anisotropic conductive layer.

24. The flexible chip package of claim 22, further comprising at least one device disposed on at least one of the first and second flexible substrates and electrically connected to at least one of the first and second redistribution layers through the conductive material penetrating at least one of the first and the second flexible substrates.

25. The flexible chip package of claim 24, wherein the at least one device comprises a sensor, a passive element, an electrostatic discharge protection element, a battery, an antenna, a connector, or a combination thereof.
